(19) United States
(12) Patent Application Publication
(10) Pub. No.: US 2011/0017588 A1
(43) Pub. Date: Jan. 27, 2011

(54) FABRICATION PROCESS FOR A THICK FILM BY MAGNETRON SPUTTERING

(76) Inventors: Kab-Seog Kim, Suwon-si (KR); Yong-Mo Kim, Seoul (KR)

Correspondence Address: STEIN MCEWEN, LLP, 1400 EYE STREET, NW, SUITE 300, WASHINGTON, DC, 20005, US

(21) Appl. No.: 12/935,612

(22) PCT Filed: Apr. 3, 2009
(86) PCT No.: PCT/KR09/01730

§ 371 Date: Sep. 30, 2010

(30) Foreign Application Priority Data
Apr. 3, 2008 (KR) 10-2008-0031268

(51) Int. Cl. C23C 14/35

(52) U.S. Cl. 204/192.12

(57) ABSTRACT

A method for forming a thick film by magnetron sputtering is provided. The method includes forming a first thin film having residual compressive stress on a board by magnetron sputtering, forming a second thin film having tensile residual stress on the first thin film by magnetron sputtering, and depositing the thick film by repeating the forming of the first and second thin films for more than one time, so that the overall residual stress is controlled within a predetermined range. According to the method, a thick film of same or different materials can be formed, while the overall stress of the thick film is controlled within an acceptable range.

### CROSS-REFERENCE TO RELATED APPLICATIONS

This application claims the benefit of PCT International Patent Application No. PCT/KR2009/001730, filed Apr. 3, 2009, and Korean Patent Application No. 10-2008-0031268, filed Apr. 3, 2008, in the Korean Intellectual Property Office, the disclosures of which are incorporated herein by reference.

### BACKGROUND OF THE INVENTION

1. Field of the Invention

Aspects of the present invention relate to a method for forming a thick film using magnetron sputtering, in which stress of a material of deposition is controlled by sputtering.

2. Description of the Related Art

The method for forming a thick film on a substrate with various materials including metal or the like, can be used in a wide range of applications.

For example, there are printed circuit boards (PCBs) which use metal, ceramic or polymer to prevent malfunctioning or shortening of lifespan of electronic components from the heat generated from the electronic components. The method for forming a metal thick film can be used in these PCBs for the electric conductivity of the metal, ceramic or polymer board.

Conventionally, wet plating which forms metal layer on a board, direct bonded copper which bonds a metal layer directly onto the board, or sputtering are generally available as the methods for forming a thick film.

FIG. 1 is a cross section view of a PCB by the conventional wet plating, and FIG. 2 is a flowchart provided to explain a process of forming a thick film by wet plating.

Referring to FIG. 1, the PCB by plating may include a board 10 as a target of plating, a seed layer 20 made from polymer resin, forming a uniform layer on an upper surface of the board 10 and forming a continuous interface, and a copper layer 30 surface treated on an upper surface of the seed layer 20.

Referring to FIG. 2, the process of forming a substrate by wet plating may generally include preparing the board 10 as a target of plating (S201), forming the seed layer 20 on a surface of the prepared board 10 (S203), and forming the copper layer 30 on the seed layer 20 by wet plating (S205).

However, due to difficulty of controlling residual stress of the layer, the wet plating has limits in the thickness of the copper layer. Accordingly, in order to form a thick film to several hundreds of μm, binding force deteriorates due to residual stress and subsequently the layer is separated. Thick films by plating also have shortcomings, including, low density, need for long time for processing due to low plating rate and subsequently complicated processing, and environmental problem due to use of toxic electrolyte.

FIG. 3 is a cross section view of a PCB by conventional direct bonding, and FIG. 4 is a flowchart provided to explain, in sequence, the process of forming a thick film by the direct bonding.

Referring to FIG. 3, the PCB by direct bonding may generally include a board 10, and a copper thin film 40 directly bonded to the surface of the board 10.

The direct bonding may generally form a substrate by the steps including: preparing the board 10 (S401), heating the board 10 and the copper thin film 40 to the eutectic point of oxygen and copper (S403), diffusing interface oxygen on the heated board 10 to fuse and thus bind the board 10 and the copper thin film 40 (S405).

Although the substrate with the good bonding is obtained by the direct bonding which uses heating up to the eutectic point (1065° C.) of oxygen and copper, due to the thermal fusing process, there is limit in the fabrication of large size substrate, and also in the range of materials of the thick film. Furthermore, since thin film is used to form a copper layer, it is difficult to fabricate a copper layer with thickness below 200 micrometer.

Other methods may be considered. For example, the sputtering in the semiconductor fabrication may be used to deposit a copper layer. However, the conventional sputtering is limited to the application as the thin film which is several nanometer of the same material for the PCB. That is, it is common belief that the thick film, usually ranging from several tens to several hundreds of μm of the same material as the PCB, is not possibly fabricated by the sputtering since control of the stress of the layer as formed is generally limited. In order to solve the above-mentioned problems, suggestions have been made, and one of these is to resolve stress using different material.

Additional method may be the laminating which uses a bonding layer. The bonding layer is applied in between a board on which a thick film is to be formed, and a thick film, and a metal thin film is bonded. This method requires thick bonding layer, and also has the limit in the thickness of the thick film since the method bonds the metal thin film which is previously prepared.

### SUMMARY OF THE INVENTION

According to one embodiment, a method for forming a thick film using magnetron sputtering, in which the stress of a depositing material is controlled by the sputtering.

According to one embodiment, a method for forming a thick film by magnetron sputtering, may include forming a first thin film having residual compressive stress on a board by magnetron sputtering, forming a second thin film having tensile residual stress on the first thin film by magnetron sputtering, and depositing the thick film by repeating the forming of the first and second thin films for more than one time, so that the overall residual stress is controlled within a predetermined range.

The thickness of the thick film may range between approximately 1 μm˜500 μm.

In another embodiment, the second thin film may be deposited first on the board, and then the first thin film may be deposited on the second thin film.

The first thin film may be formed within the compressive stress ranging from about −10 GPa to about −0.0001 GPa, and the second thin film may be formed within tensile stress from about 0.0001 GPa to about 10 GPa.

The depositing the first thin film may include generating plasma for sputtering using DC power, so that the first thin film has the compressive stress within said compressive stress range, and the DC power may desirably be controlled so that particles sputtered by the plasma have energy below 5 eV.

The depositing the second thin film may include generating plasma for sputtering using DC pulse power or AC power, so that the second thin film has the tensile stress within said tensile stress range, and the DC pulse power or AC power may be controlled so that particles sputtered by the plasma have energy from about 5 eV to about 100 eV.

According to an embodiment, by controlling the stress through the sputtering control, a thick film can be formed even when the same material is deposited as the first thin film and the second thin film.

According to one embodiment, by controlling the stress of the deposited material by magnetron sputtering, the thick film of not only different materials, but also the same material, can be formed.

Furthermore, the method for forming a thick film according to an embodiment controls the flux of the plasma by a plurality of vapor deposition sources to thus control the power of the vapor deposition sources respectively, which is simple and efficient.

According to an embodiment, the method for forming a thick film uses sputtering and thus provides improvements from the conventional methods, including, increase of bonding between board and thick film, reduction of time for forming thick film, increase of productivity, and decrease of unit cost.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a cross section view of a printed circuit board (PCB) by conventional wet plating;

FIG. 2 is a flowchart provided to explain the process of forming a thick film by wet plating;

FIG. 3 is a cross section view of a PCB by conventional direct bonding;

FIG. 4 is a flowchart illustrating the process of forming a thick film by direct bonding in sequence;

FIG. 5 is a cross section view of a substrate of a PCB fabricated by a method for forming a thick film according to an embodiment;

FIG. 6 is a view schematically illustrating the structure of sputter applicable in the fabrication process according to an embodiment;

FIG. 7 illustrates the fabrication process to explain a method for forming a thick film according to an embodiment;

FIG. 8 shows photographs of particles sputtered at DC pulse voltage with different duty cycles;

FIG. 9 is a graphical representation of measurement of the energy of the particles sputtered at DC pulse voltage with different duty cycles; and

FIG. 10 is a photograph of a cross section of a substrate of a metal PCB fabricated by the method according to an embodiment.

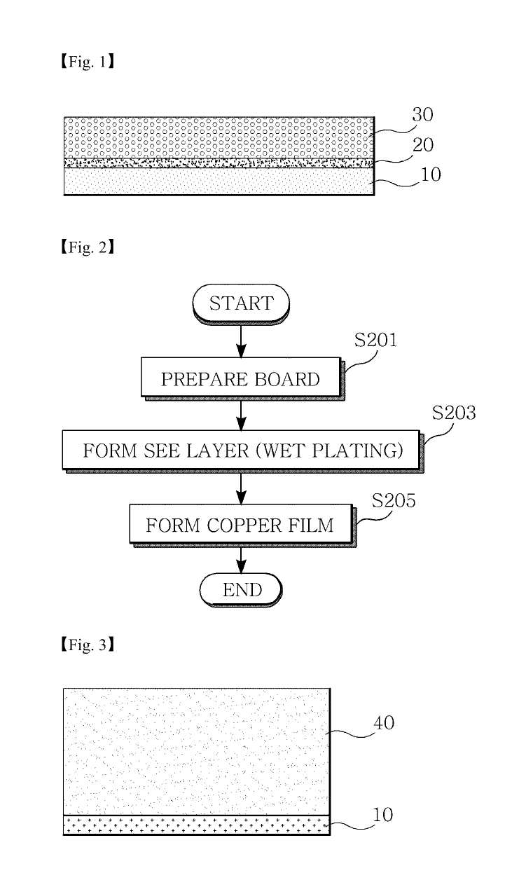

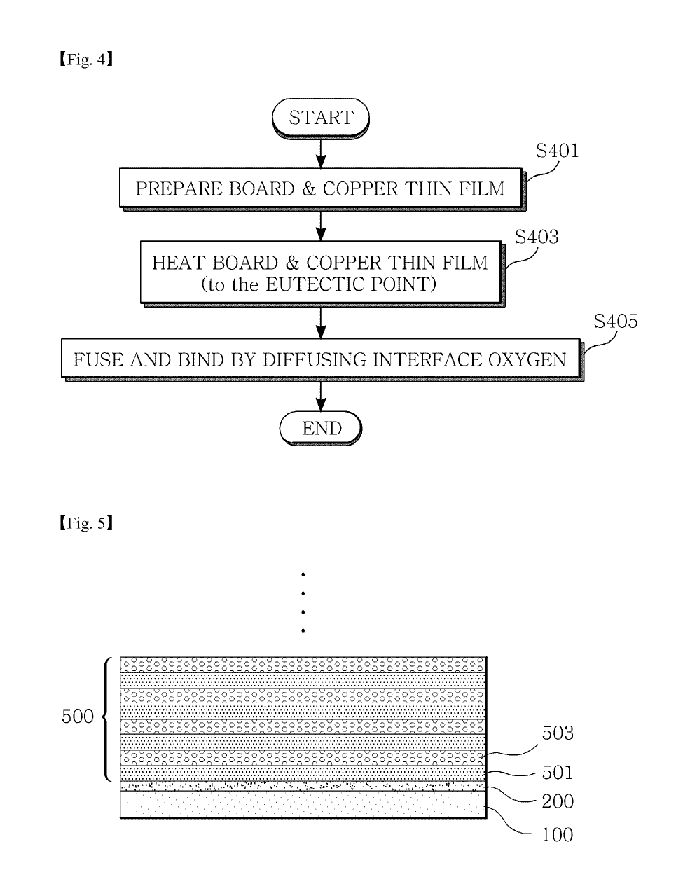

### DETAILED DESCRIPTION OF THE EMBODIMENTS

Certain exemplary embodiments of the present inventive concept will now be described in greater detail with reference to the accompanying drawings.

The method for forming a thick film according to an embodiment may be used in a wide range of applications where it is necessary to deposit thick films by magnetron sputtering for physical vapor deposition (PVD). One of those applications may be forming a thick film on a PCB formed on metal, ceramic or polymer board as the electrically-conductive layer, and an embodiment will be explained below with reference to this particular example.

FIG. 5 is a cross section view of a substrate of the PCB fabricated by a method for forming a thick film according to an embodiment, illustrating a thick film fabricated by the method for forming thick film according to an embodiment.

Referring to FIG. 5, the substrate of the PCB may include a board 100, a seed layer 200 formed on the surface of the board 100, and a thick film 500 formed on an upper surface of the seed layer 200. The thick film 500 may include a plurality of first and second thin films 501, 503. The thick film 500 is to be processed to a wiring to electrically connect electrical or mechanical components which will be mounted on the top surface after the fabrication of the substrate is completed. Herein, the first and second thin films 501, 503 may be deposited alternatively and repeatedly for more than one time to thereby form the thick film 500, and formed by the method for forming thick film according to an embodiment.

The board 100 may be made from a variety of materials, including, but not limited to, ceramic, metal, polymer, or film. The ceramic may preferably include one or a plurality of materials selected from aluminum oxide (Al2O3), aluminum nitride (AlN), silicon nitride (Si3N4), beryllium oxide (BeO), barium oxide (BaO), boron nitride (BN), and sapphire. The metal may include aluminum (Al), copper (Cu), stainless and magnesium (Mg). The polymer may include polycarbonate (PC), polyethylene terephtalate (PET), polymethylmethacrylate (PMMA), polyimide (PI), polyethylene naphthalene (PEN), polyether sulfone (PES), liquid crystal polymer (LCP), polytetrafluoroethylene (PTFE). In the example illustrated in FIG. 5, the seed layer 200 is prepared between the thick film 500 and the board 100. Alternatively, the thick film 500 may be formed directly on the board 100 of the exemplary material explained above.

The thick film 500 may be made from a variety of materials including metal or ceramic, and the first and second thin films 501, 503 may be made from materials different from each other. The first and second thin films 501, 503 may also be made from the same material. The PCB of FIG. 5 may be desirably made from a single material with good electric conductivity, such as, but not limited to, copper (Cu), gold (Au), or silver (Ag).

The first and second thin films 501, 503 may be formed by sputtering for PVD, and preferably, by magnetron sputtering.

The seed layer 200 may be employed for the purpose of increasing binding force between the board 100 and the first thin film 501 or providing electrical insulation, but not required essentially.

The method for forming a thick film according to an embodiment involves repeatedly depositing the first and second thin films 501, 503 in an alternate order. By the above processing, the overall stress of the thick film 500 is offset to an acceptable range, since the first and second thin films 501, 503 have different stresses by the sputtering. For example, the first thin film 501 may be controlled to have residual compressive stress, while the second thin film 503 may be controlled to have tensile residual stress, or vice versa. Due to the control on the stress through the control on the deposition process, the method for forming thick film according to an embodiment has no limit in the range of materials for the thick film so that it is possible to form the thick film using not only different types of materials, but also the same type of material.

That is, the method according to an embodiment enables deposition of the thick film, and even the thick film of same material, which has been considered impossible in the conventional methods which could limitedly control the stress by varying the materials of the repeatedly deposited thin layers to cause offset of stress.

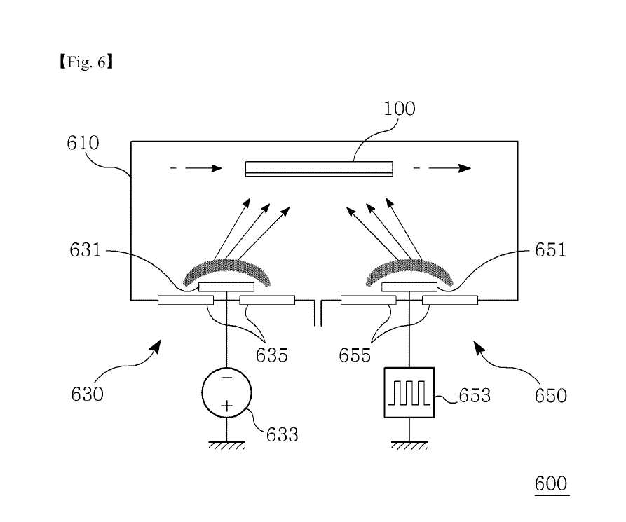

FIG. 6 schematically illustrates the structure of sputter applicable in the process according to an embodiment, and FIG. 7 illustrates a process provided to explain a method for forming a thick film according to an embodiment.

The method for forming a thick film according to an embodiment will be explained in greater detail below, with reference to FIG. 7.

Note that FIG. 6 omits the illustration of the other components of the sputter, including inert gas suction/discharge means, cooling means, or others, and the explanation for these will also be omitted.

Referring to FIG. 6, the sputter 600 may include a first vapor deposition source 630 and a second vapor deposition source 650 formed in a chamber 610. The first vapor deposition source 630 may include a first target 631, a DC power device 633 to supply power to the first target 631, and a magnetron 635. The second vapor deposition source 650 may include a second target 651, a DC pulse power device 653 to supply DC pulse to the second target 651, and a magnetron 655. The sputter 600 may include a plurality of first and second vapor deposition sources 630, 650, and the entire vapor deposition sources may be formed within one single chamber 610, or each may be formed in different separate chambers. The interior of the chamber 610 may be charged with inert gas to generate plasma, including, but not limited to, argon (Ar).

The second vapor deposition source 650 may include an AC power device, instead of the DC pulse power device 653, to supply AC power to the second target 651. The example where the DC pulse device 653 is employed will be explained below.

The magnetrons 635, 655 form magnetic fields to trap the plasma generated in the chamber 610 within the proximity to the first and second targets 631, 651. As explained above, the first and second targets 631, 651 may be made from the same or different materials.

The chemically-inert gas, such as argon (Ag) is introduced into the chamber 610, and the DC power device 633 and the DC pulse power device 653 supply power to the first and second targets 631, 651, so that deposition by sputtering begins. By the sputter 600 illustrated in FIG. 6, the first and second thin films 501, 503 may be deposited sequentially in the chamber through a series of continuous processing, as the board 100 is advanced at a predetermined speed.

Referring to FIG. 7, the thick film 500 may preferably be made to thickness ranging approximately between 1 μm˜500 μm, which may be achieved by offsetting the residual stress of the thick film 500 or the entire substrate of the PCB to an acceptable range by repeatedly depositing the first and second thin films 501, 503, which are from 1 nm to 10 μm thick each. Accordingly, the problems associated with the stress in the conventional manner of forming a thick film, are resolved.

### <Step 701: Forming First Thin Film>

The argon inside the chamber 610 turns to plasma as the DC power device 633 operates. The plasma is trapped in the proximity to the first target 631 due to the magnetic fields by the magnetron 635. Positively-charged argon ions are pulled in by the first target 631 which is negatively-charged, and thus collided. Due to the impact, the particles of the first target 631 are sputtered from the first target 631. The sputtered particles of the first target 631 are deposited on the seed layer 200, forming the first thin film 501 of the material of the first target 631. In one example, the pressure of the chamber 610 for sputtering may preferably be between approximately 1˜10 mTorr.

Accordingly, the first thin film 501, which is formed as the sputtered particles of the first target 631 by the first vapor deposition source 630 are deposited, has the residual compressive stress.

Since the plasma formed by the DC power has relatively lower energy and ion flux than the plasma by the DC pulse or AC power, the sputtered particles of the first target 631 also have the lower energy and ion flux. As the low-energy particles are deposited on the seed layer 200, the first thin film 501 having the residual compressive stress is formed. The compressive stress may be controlled in the range from about −10 GPa to about −0.0001 GPa. To this end, it is preferable to control the DC power of the DC power device so that the sputtered particles by the DC plasma have the energy no more than 5 eV.

### <Step 703: Forming a Second Thin Film>

The second vapor deposition source 650 operates under the same pressure condition, and the second thin film 503 is deposited on the first thin film 501 in the same manner.

The second thin film 503, formed by the particles sputtered from the second target 651 by the second vapor deposition source 650 operated by the DC pulse power (or AC power), has the tensile residual stress.

Since the plasma formed by the DC pulse power (or AC power) has relatively higher energy and ion flux, the sputtered particles from the second target 651 also have the higher energy and flux. As such particles are deposited on the first thin film 501, the second thin film 503 having tensile residual stress, is formed. The tensile stress of the second thin film 503 may be controlled in a range from about 0.0001 GPa to about 10 GPa. To this end, it is preferable to control the DC pulse (or AC) power of the DC pulse (or AC) power device so that the energy E of the sputtered particles by the DC pulse (or AC) plasma satisfy:

5 eV≦E≦100 eV [Mathematical expression 1]

The DC pulse power may be controlled by controlling one of voltage size, duty cycle, or frequency.

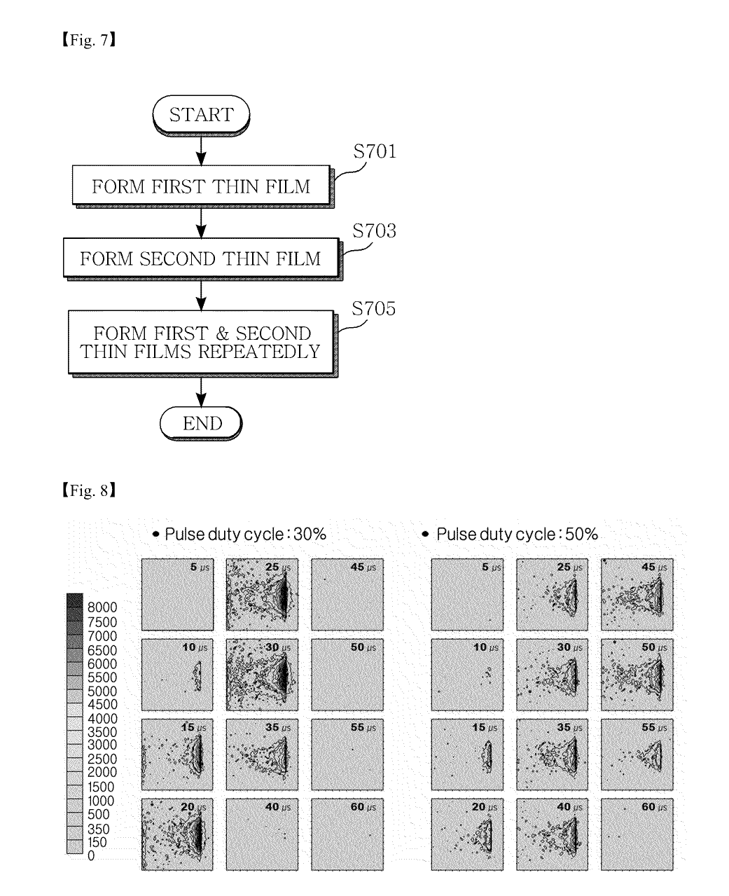

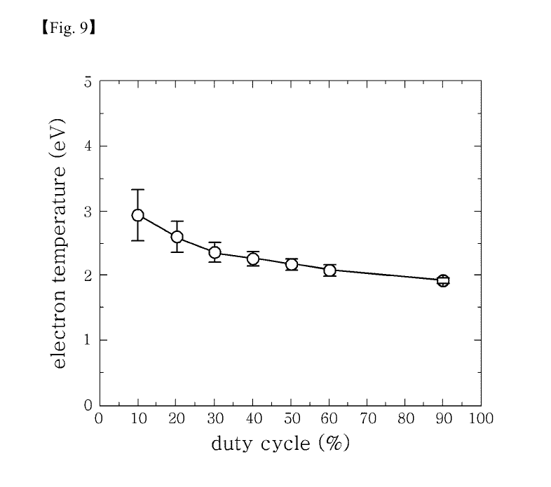

FIG. 8 shows photographs of particles sputtered at DC pulse voltage with different duty cycles. Referring to FIG. 8, the sputtered particles generated with 30% duty cycle of the DC pulse voltage (12 photographs on the left-hand side) have higher flux than the sputtered particles generated with 50% duty cycle (12 photographs on the right-hand side). Accordingly, the sputtered particles generated with the DC pulse voltage have higher flux than the sputtered particles generated with the 100% duty cycle of power voltage. FIG. 9 is a graphical representation of measurement of the energy of the particles sputtered at DC pulse voltage with different duty cycles. According to FIG. 9, the sputtered particles with the DC pulse voltage have far higher energy than the sputtered particles with the DC power. Accordingly, the residual compressive stress of the first thin film 501 and the tensile residual stress of the second thin film 503 which are in offset relation with each other, or the control parameters of the DC power device 633 and the DC pulse power device 653, may be obtained by experiments.

### <Step 705: Forming a Thick Film>

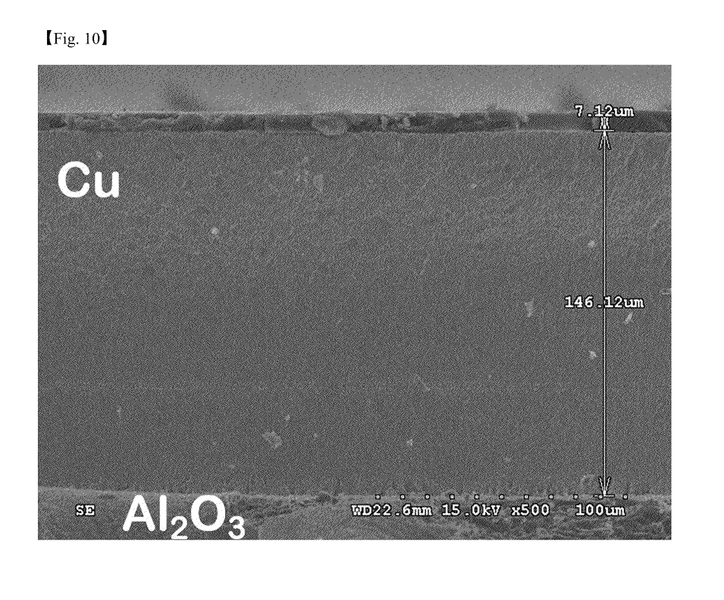

The thick film 500 may be formed to a thickness ranging from about 1 μm to about 500 μm. The residual compressive stress of the first thin film 501 is offset entirely or partially by the tensile residual stress of the second thin film 503. The overall stress of the thick film 500 is controlled, as the first and second thin films 501, 503 are repeatedly formed in an alternate fashion to have offset of stress. FIG. 10 is a photograph of a cross section of a substrate of a metal PCB fabricated by the method according to an embodiment. Referring to FIG. 10, a high density conductive thick film which is 150 μm thick is deposited on the insulating Al2O3 layer.

The residual stresses of the first and second thin films 501, 503 may be expressed by:

σ=n(Sc+St) [Mathematical expression 2]

where, σ is the total residual stress of the thick film 500, Sc is compressive stress of the first thin film 501, St is tensile stress of the second thin film 503, and n is a number of first and second thin films 501, 503 which is an integer above 1. n=4 for the substrate 400 of FIG. 5, meaning that the first and second thin films 501, 503 are deposited repeatedly by four times. The integer n may vary even in the same thickness think film 500, depending on the thickness of the first and second thin films 501, 503, or the thickness of the entire thick film 500. Since Sc and St may be different from each other, the total stress σ may not be in the acceptable range (0), or offset to 0. The material on which the thick film 500 is formed, i.e., the stress of the entire substrate of the PCB may have the stress corresponding to the total residual stress σ of the thick film 500 and/or the stress of the seed layer 200.

When n=1, there are one single first thin film and one single second thin film, and it suggests that S705 is not performed.

### Embodiment 1

Depending on embodiments, the second thin film 503 with the tensile residual stress may be deposited first, and then the first thin film 501 with the residual compressive stress may be formed on the second thin film 503.

### Embodiment 2

The method for forming a thick film according to an embodiment may be applied in the fabrication of various products including the substrate of the PCB of FIG. 5 explained above.

In the PCB of FIG. 5, the seed layer 200, which is formed first on the board 100, may be formed by magnetron sputtering.

The seed layer 200 may desirably be formed to thickness of 1 nm ˜10 μm and work as a barrier film. The seed layer 200 of the PCB of FIG. 5 may provide electrical insulation between the electrically-conductive thick film 500 and the board 100, and also transmission of the heat generated at the thick film 500 to the board 100. To this end, the seed layer 200 by sputtering may be made from a low dielectric material with good thermal transmission and electrical insulation, and made from various materials including, but not limited to, oxide, nitride, diamond-like carbon (DLC) or carbide depending on the types and chemical properties of the board 100 and the thick film 500.

The oxide may include silicon oxide (SiOX), titanium oxide (TiOX), aluminum oxide (AlXOy), or chrome oxide (CrOX), and the nitride may include silicon nitride (SiXNy), titanium nitride (TiXNy), aluminum nitride (AlN), or boron nitride (BN). The carbide may include silicon carbide (SiC), titanium carbide (TiC), or chrome carbide (CrC).

Depending on occasions, the seed layer 200 may be made from the same material or different materials in a multi-layer fashion. The seed layer is particularly formed from different materials in a multi-layer fashion to provide multi layers of good binding property to the board 100 and to the electrically-conductive thick film 500, when there is no seed layer material having an optimum chemical binding to both the board 100 and the thick film 500.

It will be necessary to control stress in the same manner as the method for forming the thick film 500, if the seed layer 200 is formed as multi layers.

Since the films are formed densely by the sputtering, the metal thick film 500 has the good electrical and thermal transmission properties. Furthermore, the thick film 500 by the sputtering forms large size layer at high speed, and thus is suitable for the fabrication of large size metal PCB in the fields such as LCD backlight circuit.

The foregoing exemplary embodiments and advantages are merely exemplary and are not to be construed as limiting the present invention. The present teaching can be readily applied to other types of apparatuses. Also, the description of the exemplary embodiments of the present inventive concept is intended to be illustrative, and not to limit the scope of the claims, and many alternatives, modifications, and variations will be apparent to those skilled in the art.

1. A method for forming a thick film by magnetron sputtering, comprising:
forming a first thin film having residual compressive stress on a board by magnetron sputtering;
forming a second thin film having tensile residual stress on the first thin film by magnetron sputtering; and
depositing the thick film by repeating the forming of the first and second thin films for more than one time, so that the overall residual stress is controlled within a predetermined range.

2. A method for forming a thick film by magnetron sputtering, comprising:
forming a second thin film with tensile residual stress on a board by magnetron sputtering;
forming a first thin film with residual compressive stress on the second thin film by magnetron sputtering; and
depositing the thick film by repeating the forming of the first and second thin films for more than one time, so that the overall residual stress is controlled within a predetermined range.

3. The method of claim 1, wherein the first thin film is formed within the compressive stress ranging from about −10 GPa to about −0.0001 GPa, and
the second thin film is formed within tensile stress from about 0.0001 GPa to about 10 GPa.

4. The method of claim 3, wherein the depositing the first thin film comprises generating plasma for sputtering using DC power, so that the first thin film has the compressive stress within said compressive stress range.

5. The method of claim 3, wherein the DC power is controlled so that particles sputtered by the plasma have energy below 5 eV.

6. The method of claim 3, wherein the depositing the second thin film comprises generating plasma for sputtering using DC pulse power or AC power, so that the second thin film has the tensile stress within said tensile stress range.

7. The method of claim 6, wherein the DC pulse power or AC power is controlled so that particles sputtered by the plasma have energy from about 5 eV to about 100 eV.

8. The method of claim 1, wherein the thickness of the thick film ranges between approximately 1 μm˜500 μm.

9. The method of claim 2, wherein the first thin film is formed within the compressive stress ranging from about −10 GPa to about −0.0001 GPa, and
the second thin film is formed within tensile stress from about 0.0001 GPa to about 10 GPa.

10. The method of claim 2, wherein the thickness of the thick film ranges between approximately 1 μm˜500 μm.
